(19) United States
(12) Patent Application Publication
(10) Pub. No.: US 2011/0017597 A1
(43) Pub. Date: Jan. 27, 2011

(54) METHOD FOR FABRICATING HYDROGEN ELECTROCHEMICAL SENSOR USING TETRAMETHYLAMMONIUM HYDROXIDE PENTAHYDRATE

(75) Inventors: Huen LEE, Daejeon (KR); Jong-Ho CHA, Daejeon (KR); Wonhee LEE, Daejeon (KR)

Correspondence Address: NELSON MULLINS RILEY & SCARBOROUGH LLP;FLOOR 30, SUITE 3000, ONE POST OFFICE SQUARE, BOSTON, MA, 02109, US

(73) Assignee: Korea Advanced Institute of Science and Technology, Daejeon (KR)

(21) Appl. No.: 12/628,542

(22) Filed: Dec. 1, 2009

(30) Foreign Application Priority Data
Jul. 27, 2009 (KR) 10-2009-0068582

(51) Int. Cl. G01N 27/26; G01R 3/00

(52) U.S. Cl. 204/431; 29/592.1

(57) ABSTRACT

The present invention relates to a method for fabricating an electrochemical sensor which can highly sensibly detect a hydrogen gas by adapting Me₄NOH.5H₂O as a proton conductor. In the present invention, Me₄NOH.5H₂O with a high ion conductivity and a reliable thermal stability is adapted as a proton conductor, and a carbon electrode on which a platinum dispersed in an organic solvent is loaded, is used as an anode. It is possible to fabricate a new type electrochemical sensor which adapts an ionic clathrate hydrate capable of reliably detecting hydrogen gas.

### TECHNICAL FIELD

The present invention relates to a method for fabricating a hydrogen electrochemical sensor using a tetramethylammonium hydroxide pentahydrate (Me₄NOH.5H₂O), and in particular to a method for fabricating an electrochemical sensor which can reliably detect a hydrogen gas by using Me₄NOH.5H₂O as a proton conductor.

### BACKGROUND ART

Hydrogen gas is considered as one of the key energy sources which might be an alternative to fossil fuels because it is environment friendly and exists a lot in nature. However hydrogen gas might be exploded when burning at a concentration of above 4% since its energy conversion is rapidly performed. Various systems for more effectively detecting hydrogen gas are currently under development. As one of the key systems under development, an electrochemical sensor is disclosed, which is known to be able to reliably detect a concentration of hydrogen gas via the changes of current or voltage.

The electrochemical method can quickly detect hydrogen gas even at a lower concentration, and the sizes of systems for detecting hydrogen gas are not advantageously limited.

A conventional hydrogen electrochemical sensor consists of an anode and a cathode for an electrochemical reaction and a proton conductor which transfers protons from the anode to the cathode. As a representative substance used in hydrogen electrochemical sensor among solid proton conductors, there are Nafions and ceramics. In the course of manufacturing sensors, Nafions have excellent ion conductivity, but have unreliable poor stability and costs a lot. Ceramics have excellent stability, but have a reliable ion conductivity only at above 600° C. Since processing is complicated, some problems might occur when ceramics are adapted to sensors.

The electrodes generally used in a hydrogen electrochemical sensor can be used by impregnating metals, which are mainly used as catalysts, in electrodes. Among the methods developed for fabricating an anode and a cathode, a method loading a metal, which operates as catalyst, onto a solid electrolyte directly is called an impregnation-reduction method. The impregnation-reduction method is characterized in that metal complexes are impregnated on a surface of a solid electrolyte and are reduced by a strong reduction agent, and metallic particles are loaded onto the surface. The electrolyte/electrode assembly has an excellent interfacial contact performance, so a desired performance can be obtained with a lower metallic impregnation amount. However, when the solid electrolyte is soluble in water or any of organic solution, an original form of electrolyte cannot be maintained, which hinders actual use.

### DISCLOSURE OF THE INVENTION

Accordingly, it is an object of the present invention to provide a method for fabricating a hydrogen electrochemical sensor using a tetramethylammonium hydroxide pentahydrate in which tetramethylammonium hydroxide pentahydrate (Me₄NOH.5H₂O) with a high ion conductivity and a thermal stability is used as a proton conductor, and a carbon electrode on which platinum dispersed in an organic solution is loaded is used as an anode. So, it is possible to fabricate an electrochemical sensor with an ionic clathrate hydrate which is to detect hydrogen gas.

It is another object of the present invention to provide a method for fabricating a hydrogen electrochemical sensor which uses tetramethylammonium hydroxide pentahydrate.

It is further another object of the present invention to provide a hydrogen electrochemical sensor which is fabricated by the above method.

In the present invention, it is possible to fabricate a hydrogen electrochemical sensor which has a fast response time and a fast recovery time even when performing sensing cycles a few tens of time using a tetramethylammonium hydroxide pentahydrate (Me₄NOH.5H₂O) having a high ion conductivity and a thermal stability as a proton conductor.

### EFFECTS

As compared to a method for fabricating a hydrogen electrochemical sensor which uses Nafions or ceramics widely used as a solid proton conductor, according to the present invention the method for fabricating a hydrogen electrochemical sensor has the following advantages.

(1) Since Me₄NOH.5H₂O, which is a kind of ionic clathrate hydrate, has a reliable ion conductivity and thermal stability, it is possible to fabricate a hydrogen sensor which operates at room temperature as an alternative to the conventional solid electrolyte including Nafions.

(2) Since Me₄NOH.5H₂O, a raw material, can be used itself without a specific chemical reaction or a certain pretreatment, the hydrogen electrochemical sensor of the present invention can be fabricated through a very simple process.

(3) Me₄NOH.5H₂O with a melting point of 68° C., is treated to melt at above melting point and is crystallized at room temperature and then is used as a proton conductor, so it is easy to fabricate a sensor in a desired size and shape.

(4) Compared with other proton conductors including Nafions, Me₄NOH.5H₂O costs less. Therefore the hydrogen sensor can be economically fabricated at a low cost. In addition, the hydrogen sensor fabricated according to a method of the present invention can effectively detect a hydrogen gas in the current measure mode, even though the concentration of hydrogen gas is below minimum explosion concentration.

### BRIEF DESCRIPTION OF THE DRAWINGS

The present invention will become better understood with reference to the accompanying drawings which are given only by way of illustration and thus are not limitative of the present invention, wherein;

FIG. 1 is a schematic view illustrating a hydrogen electrochemical sensor of a current measure mode in which Me₄NOH.5H₂O of the present invention functions as a proton conductor between a carbon electrode (anode) on which platinum nano particles are loaded and a carbon electrode (cathode) which is loaded with nothing;

FIG. 2 is a view of a Cole-Cole plot of Me₄NOH.5H₂O which functions as a proton conductor between a carbon electrode (anode) on which porous platinum is loaded and a carbon electrode (cathode) which is loaded with nothing;

FIG. 3 is a view showing a powder XRD pattern of a carbon electrode (anode) on which porous platinum is loaded;

FIG. 4 is a SEM photo showing a carbon electrode (anode) on which porous platinum is loaded;

FIGS. 5A and 5B are graphs showing hydrogen detection characteristics when being exposed to hydrogen-nitrogen mixed gas of 10% and 1%, respectively, under the voltage of 0.05V when the amount of platinum loaded on anode is 6.18 mg·cm⁻²;

FIGS. 5C and 5D are graphs showing hydrogen detection characteristics when being exposed to hydrogen-nitrogen mixed gas of 10% and 1%, respectively, under the voltage of 0.05V when the amount of platinum loaded on anode is 3.50 mg·cm⁻²; and

FIG. 6 is a graph showing the hydrogen detection characteristics based on the voltages 0.01V, 0.05V and 0.1V, respectively, when being exposed to hydrogen-nitrogen mixed gas of 0.1% when the amount of platinum loaded on anode was 6.18 mg·cm⁻².

### MODES FOR CARRYING OUT THE INVENTION

Since tetramethylammonium hydroxide hydrate (Me₄NOH.×H₂O), one of representative ionic clathrate hydrate, has a high proton conductivity, it seems to have a high possibility of being used as a solid electrolyte. However since it has a low thermal stability, it remains in a liquid state at above room temperature, so its application as an electronic device remains very limited. Since only tetramethylammonium hydroxide pentahydrate (Me₄NOH.5H₂O) has a melting point of 68° C., it can be applied as a solid electrolyte at around room temperature. The inventors of the present application tried to fabricate an electrochemical sensor which has a fast response and recovery time even when it passes through sensing cycles a few tens of time at near 4% of the minimum explosion concentration of hydrogen gas by using Me₄NOH.5H₂O as a proton conductor. According to the present invention, it provides a hydrogen electrochemical sensor in which an ionic clathrate hydrate Me₄NOH.5H₂O with a high ion conductivity and thermal stability is disposed between electrodes.

The method for fabricating a hydrogen electrochemical sensor using tetramethylammonium hydroxide pentahydrate according to the present invention has the following process comprising:

a step (i) for slowly adding platinum powder (Pt black) to distilled water; substantially moisturizing a mixture of the platinum powder and the distilled water; subsequently adding nafion perfluorinated resin solution; and then agitating and dispersing to prepare a first dispersed solution;

a step (ii) for adding isopropyl alcohol to the first dispersed solution and dispersing catalyst particles to prepare a second dispersed solution while repeatedly performing agitation and ultrasonic wave treatment;

a step (iii) for uniformly loading the second dispersed solution on a surface of an electrically conductive carbon electrode and vaporizing organic solvent, which is loaded together along with the second dispersed solution, into the air and loading platinum on the carbon electrode and obtaining an anode;

a step (iv) for placing the anode in one side of a cell made of Teflon and placing a carbon electrode, which is loaded with nothing, in the opposite side of the anode as a cathode and connecting the anode and the cathode through a current meter;

a step (v) for injecting tetramethylammonium hydroxide pentahydrate (Me₄NOH.5H₂O) between the anode and the cathode inside the Teflon cell in a liquid state at above melting point and crystallizing at room temperature for at least one day long and fabricating a proton conductor.

In the above process, platinum powder functions like a catalyst for promoting an electrochemical reaction. And Me₄NOH.5H₂O is solidified through crystallization after it is injected at above melting point, so good interfacial contacts between the electrodes are obtained, so it is possible to obtain a high ion conductivity since other resistances except for a bulk resistance of a solid electrolyte itself do not exist. In addition, the particles of platinum catalyst layer loaded onto the anode have about 8.8 nm sizes in average along with a high crystalline property and a porous structure. So hydrogen gas can be fast spread, and an electrochemical reaction of hydrogen gas can be promoted.

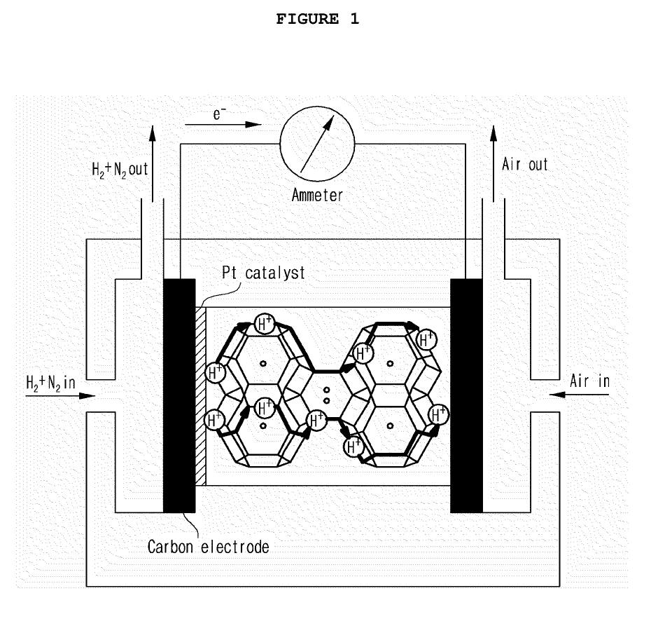

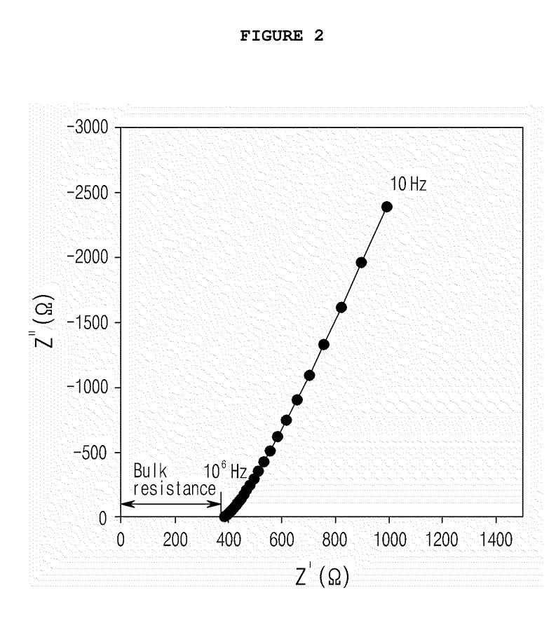

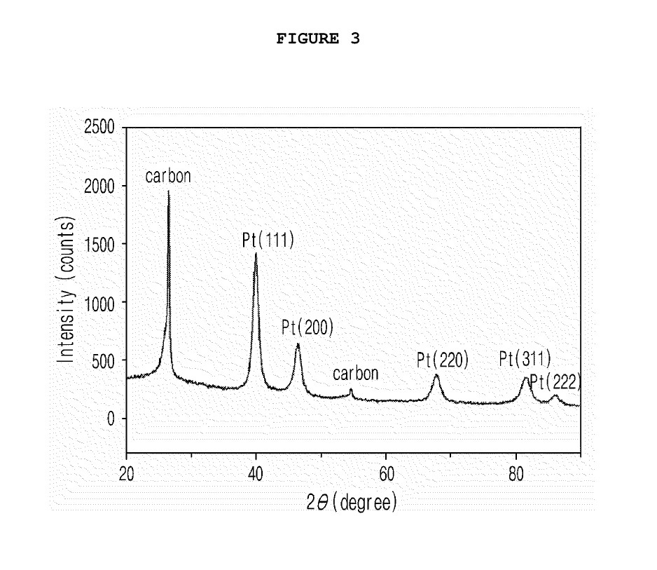

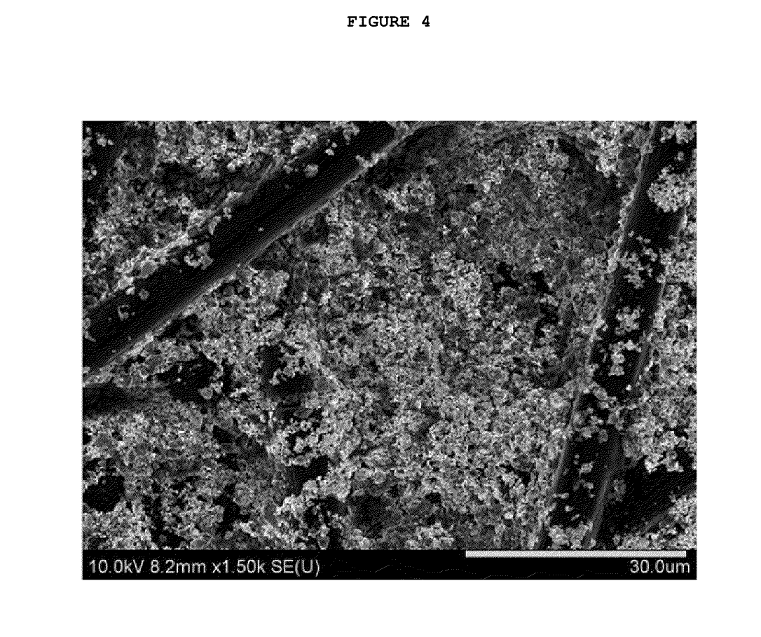

FIG. 1 is a schematic view illustrating a hydrogen electrochemical sensor of a current measure mode fabricated according to the present invention, and FIG. 2 is a view of a Cole-Cole plot of Me₄NOH.5H₂O which functions as a proton conductor between a carbon electrode (anode) on which porous platinum is loaded and a carbon electrode (cathode) which is loaded with nothing. As seen from the view of impedance diagram of FIG. 2, Me₄NOH.5H₂O and the electrodes have good contacts in the interfaces, and since other resistances except for the bulk resistance of a solid electrolyte do not exist, a high ion conductivity is obtained. The crystalline property and the size of particles of platinum catalyst loaded on the surface of the anode as well as the ion conductivity of Me₄NOH.5H₂O are main factors of influencing the changes of the current which occurs in the course of electrochemical reaction. A research shows that the size of catalyst particles and porous structure influence the performance of sensor like determining the limit concentration of hydrogen gas (Refer to M. Sakthivel, W. Weppner, Sensors, 2006, 6, 284-297). FIG. 3 is a view illustrating a powder XRD pattern of a carbon electrode (anode) on which porous platinum is loaded and the peaks with respect to platinum and carbon electrode. The peak of the loaded platinum catalyst has a width wider than that of platinum of bulk state, which means that nano particles with micro sizes are loaded on the electrodes, nevertheless it shows very high crystalline properties. The average sizes of platinum particles are about 8.8 nm from the peak widths of (1 1 1) surface based on the formula of Scherrer. FIG. 4 is a SEM photo of a carbon electrode (anode) on which porous platinum is loaded. Based on the result of observation on morphology of an anode surface using SEM, it clearly represents that the clusters of platinum particles having a few tens to a few hundreds of nano meter sizes are well loaded between the carbon fibers. In the surface morphology, a number of holes existing between platinum particles are extended into the inner structures in a porous network shape. It can be assumed that the holes consistently connected in the interior allow hydrogen gases into the catalyst layer. Since the platinum nano particles act as a phase boundary of Me₄NOH.5H₂O, hydrogen gas and catalyst, it functions as a reaction point promoting the electrochemical reaction of hydrogen gas.

The hydrogen electrochemical sensor fabricated according to the present invention makes it possible to detect a hydrogen gas based on a change in the current which occurs by means of an electrochemical reaction as a hydrogen gas is split into proton and electron in anode.

The preferred embodiments of the present invention will be described in more details. The embodiments are given only for describing the present invention in more details, and the scope of the present invention is not limited by means of the disclosed embodiments.

### Embodiment 1

### Fabrication of Hydrogen Electrochemical Sensor of Current Measure Mode

Platinum powder (Pt black) of 0.15 g was slowly added to distilled water of 0.3 ml and was substantially moisturized, and 5% nafion perfluorinated resin solution of 0.258 ml was added and dispersed using a magnet agitator. 5% isopropyl alcohol of 2 ml was added, and catalyst particles were well dispersed while repeating agitation and ultrasonic wave treatment. Dispersed solution was uniformly loaded onto a surface of electrically conductive carbon electrode using a brush, and the loaded organic solution was vaporized in the air, and platinum of 3.40 mg and 1.93 mg was loaded on a carbon electrode with a surface of 0.5 cm×1.0 cm, so that anode was fabricated.

The anode was placed in one side of a cell made of Teflon, and a carbon electrode, which was unloaded, was placed in the opposite side of the anode as a cathode, and the anode and the cathode were connected through a current meter. Me₄NOH.5H₂O was injected between the anode and the cathode inside the Teflon cell in liquid state at above melting point and was crystallized at room temperature for at least one day and was used as a proton conductor. FIG. 1 is a schematic view illustrating a hydrogen electrochemical sensor of a current measure mode according to the present invention.

### Embodiment 2

### Change of Hydrogen Detection Characteristic Based on the Amount of Platinum Loaded on Anode

The hydrogen detecting characteristics are compared when being exposed to a hydrogen-nitrogen mixed gas while adjusting the amount of platinum loaded on anode to 6.18 mg·c m⁻² and 3.50 mg·c m⁻², respectively.

### Embodiment 2-1

When hydrogen-nitrogen mixed gas of concentration of 10% and 1% was injected into an anode at a rate of 200 cm³min⁻¹ in the hydrogen electrochemical sensor fabricated according to the method of the embodiment 1, the current sharply increased and become maximum with response time of 6 seconds and 20 seconds, respectively. In case of mixed gas of 1% with lower concentration, the maximum value of the current was relatively lower due to lower partial pressure of hydrogen, which meant that electrochemical sensor, which used ionic clathrate hydrate as solid electrolyte, had enough sensitivity in a concentration range of 1˜10% near the lowest explosion concentration of hydrogen. The current increased as gas was injected starts lowering upon disconnection of supply, and it had recovery time of about 40 seconds without having any influences on the concentration of hydrogen gas. Moreover, Me₄NOH.5H₂O, which had been used as proton conductor, was not decomposed even when proton was continuously injected for longer sensing time, but exists stably. With the help of stable hydrate, the maximum value of current was maintained constantly at each cycle at which hydrogen-nitrogen mixed gas was injected.

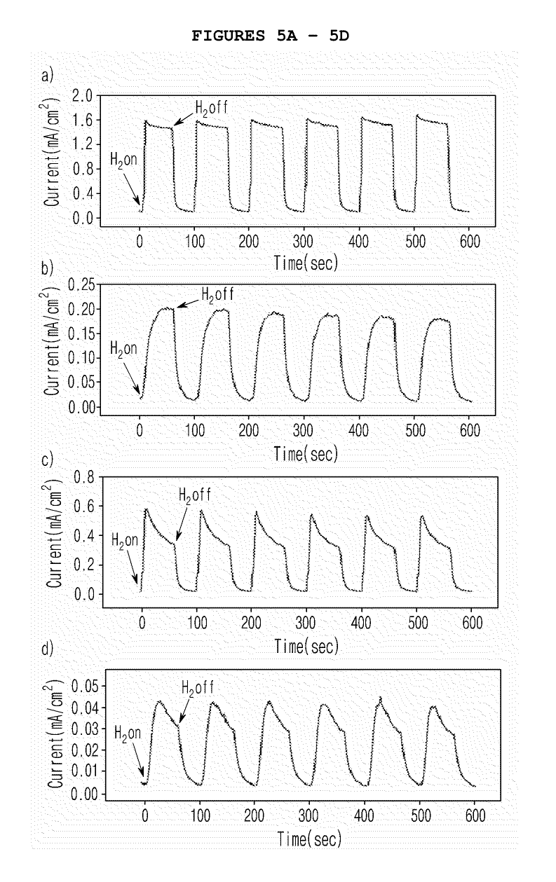

FIGS. 5A and 5B are graphs showing hydrogen detection characteristics when being exposed to hydrogen-nitrogen mixed gas of 10% and 1%, respectively, under the voltage of 0.05V when the amount of platinum loaded on anion is 6.18 mg·cm⁻².

### Embodiment 2-2

Since catalyst determined reaction rate by lowering activation energy, the amount of platinum catalyst greatly influenced the level of current. As a result of the test performed in the same method as the embodiment 2-1 using the decreased amount of catalyst of 3.50 mg·c m⁻², the maximum value of current was much lower, but the response time and recovery speed were almost same.

FIGS. 5C and 5D are graphs showing hydrogen detection characteristics when being exposed to hydrogen-nitrogen mixed gas of 10% and 1%, respectively, under the voltage of 0.05V when the amount of platinum loaded on anion is 3.50 mg·cm⁻².

### Embodiment 3

### Change of Response Rate Based on Voltage Applied

Along with aforesaid influences according to the concentration of hydrogen gas and the amount of platinum catalyst, the changes of the current based on time when hydrogen-nitrogen mixed gas of 0.1% was injected were measured according to the different voltages of 0.01V, 0.05V and 0.1V respectively, so as to test the response time. As a result, it was shown that the response time was decreased as higher voltage was applied in the above range of voltage.

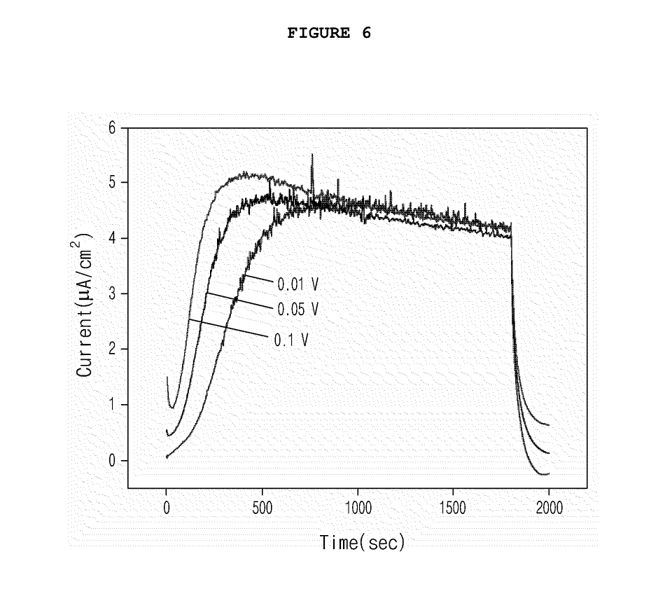

FIG. 6 is a graph showing the hydrogen detection characteristics based on the voltages 0.01V, 0.05V and 0.1V, respectively, when being exposed to hydrogen-nitrogen mixed gas of 0.1% when the amount of platinum loaded on anode was 6.18 mg·cm⁻².

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. A method for fabricating a hydrogen electrochemical sensor using tetramethylammonium hydroxide pentahydrate, comprising:
a step (i) for slowly adding platinum powder (Pt black) to distilled water; substantially moisturizing a mixture of the platinum powder and the distilled water; subsequently adding nafion perfluorinated resin solution; and then agitating and dispersing to prepare a first dispersed solution;
a step (ii) for adding isopropyl alcohol to the first dispersed solution and well dispersing catalyst particles to prepare a second dispersed solution while repeatedly performing agitation and ultrasonic wave treatment;
a step (iii) for uniformly loading the second dispersed solution on a surface of an electrically conductive carbon electrode and vaporizing organic solvent, which is loaded together along with the second dispersed solution, into the air and loading platinum on the carbon electrode and obtaining an anode;
a step (iv) for placing the anode in one side of a cell made of Teflon and placing a carbon electrode, which is loaded with nothing, in the opposite side of the anode as a cathode and connecting the anode and the cathode through a current meter;
a step (v) for injecting tetramethylammonium hydroxide pentahydrate (Me₄NOH.5H₂O) between the anode and the cathode inside the Teflon cell in a liquid state at above melting point and crystallizing at room temperature for at least one day long and fabricating a proton conductor.

2. A hydrogen electrochemical sensor fabricated by the method of claim 1, comprising a solid clathrate hydrate disposed between an anode on which platinum particles are uniformly loaded and a cathode which is loaded with nothing.

3. A hydrogen electrochemical sensor of claim 2, wherein a Me₄NOH.5H₂O is injected at above melting point in a liquid state and is solidified through a crystallizing process, so a higher ion conductivity is obtained with the help of non-presence of other resistances except for a bulk resistance of a solid electrolyte along with good interfacial contacts with both electrodes.

4. A hydrogen electrochemical sensor of claim 2, wherein particles of a platinum catalyst layer loaded on an anode has a size of about 8.8 nm in average and has a high crystalline property and a porous structure, which leads to a fast spreading of hydrogen gas while promoting an electrochemical reaction of hydrogen gas.

5. A hydrogen electrochemical sensor of claim 2, wherein when hydrogen-nitrogen mixed gases of 10% and 1% are injected, response time is 6 seconds and 20 seconds, respectively, and recovery time of each gas is about 40 seconds.
